(19) United States
(12) Patent Application Publication
(10) Pub. No.: US 2026/0194830 A1
(43) Pub. Date: Jul. 9, 2026

(54) LITHOGRAPHY APPARATUS, ARTICLE MANUFACTURING METHOD, INFORMATION PROCESSING APPARATUS, AND STORAGE MEDIUM

(71) Applicant: CANON KABUSHIKI KAISHA, Tokyo (JP)

(72) Inventors: TOSHITAKA UMEMOTO, Tochigi (JP); TERUHISA NAWAMAKI, Tochigi (JP); JUN KAWASHIMA, Tochigi (JP)

(21) Appl. No.: 19/382,562

(22) Filed: Nov. 7, 2025

(30) Foreign Application Priority Data
Nov. 14, 2024 (JP) 2024-199204

(51) Int. Cl. G03F 7/00; G03F 9/00

(52) U.S. Cl. CPC G03F 7/70733; G03F 7/70525; G03F 7/70725; G03F 7/70758; G03F 7/70775; G03F 9/7003

(57) ABSTRACT

A lithography apparatus is configured to execute a job of performing pattern transfer on one or more substrates having a plurality of shot regions using one or more originals. The apparatus includes an original stage, and a controller that determines a transfer procedure that can complete the job at maximum speed based on a number of originals to be used in the job and a number of substrates to be processed.

### BACKGROUND

### Field of the Technology

The present disclosure relates to a lithography apparatus, an article manufacturing method, an information processing apparatus, and a storage medium.

### Description of the Related Art

An exposure apparatus can execute a process of performing exposure using a plurality of originals with respect to one substrate. A transfer process step of applying such a process to a substrate for one lot will be considered. In this transfer process step, exposure is performed while sequentially exchanging a plurality of originals for each substrate to be sequentially input.

For the purpose of improved throughput, shortening of the time required for the transfer process step needs to optimize the order of inputting the substrate and the original (e.g., see Japanese Patent Laid-Open No. 2008-205309). For example, when the transfer process is performed on three substrates using three originals A, B, and C, the transfer process is normally performed in the use order of the original designated by the user, and thus the original is used in the order of A->B->C, A->B->C, A->B->C, . . . . On the other hand, when the order is changed to A->B->C, C->B->A, A->B->C, . . . , the number of times of original exchange is reduced (in this case, reduced by one time) as compared with the normal time, and the time required for the transfer process can be shortened.

However, in an apparatus configuration in which only one original stage and one original pre-alignment stage are disposed, it is necessary to convey the original from an original stocker to an original pre-alignment stage when the third and subsequent originals are used. It takes a relatively long time for this conveyance of the original from the original stocker to the original pre-alignment stage. Therefore, even if the use order of the original is optimized, this conveyance of the original becomes a bottleneck, and the throughput improvement effect can be limited.

### SUMMARY

The present disclosure provides an advantageous technology for improving throughput regarding a jobs of performing a transfer process using one or more originals with respect to one or more substrates.

The present disclosure in its one aspect provides a lithography apparatus configured to execute a job of performing pattern transfer on one or more substrates having a plurality of shot regions using one or more originals, the lithography apparatus including an original stage, and a controller that determines a transfer procedure that can complete the job at maximum speed based on a number of originals to be used in the job and a number of substrates to be processed.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view illustrating a configuration of an exposure apparatus.

FIG. 2 is a flowchart of processing for determining a transfer process method.

FIG. 3 is a flowchart of a collective transfer process method.

FIG. 4 is a flowchart of a division transfer process method in a case where the number of originals to be used is an even number.

FIG. 5 is a flowchart of a division transfer process method in a case where the number of originals to be used is an odd number.

FIG. 6 is a flowchart of a single transfer process method.

FIGS. 7A to 7C are timing charts of each transfer method.

FIGS. 8A to 8C are timing charts of each transfer method.

FIGS. 9A to 9C are timing charts of each transfer method.

FIG. 10 is a view showing an expression for calculating a transfer process step time of each transfer process method.

FIG. 11 is a view illustrating a configuration of a controller.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

The present disclosure relates to a lithography apparatus configured to be able to execute a job of performing pattern transfer on one or more substrates having a plurality of shot regions using one or more originals. The lithography apparatus can be, for example, an exposure apparatus, an imprint apparatus, or the like. Hereinafter, in order to provide a specific example, an embodiment in a case where the lithography apparatus is an exposure apparatus will be described.

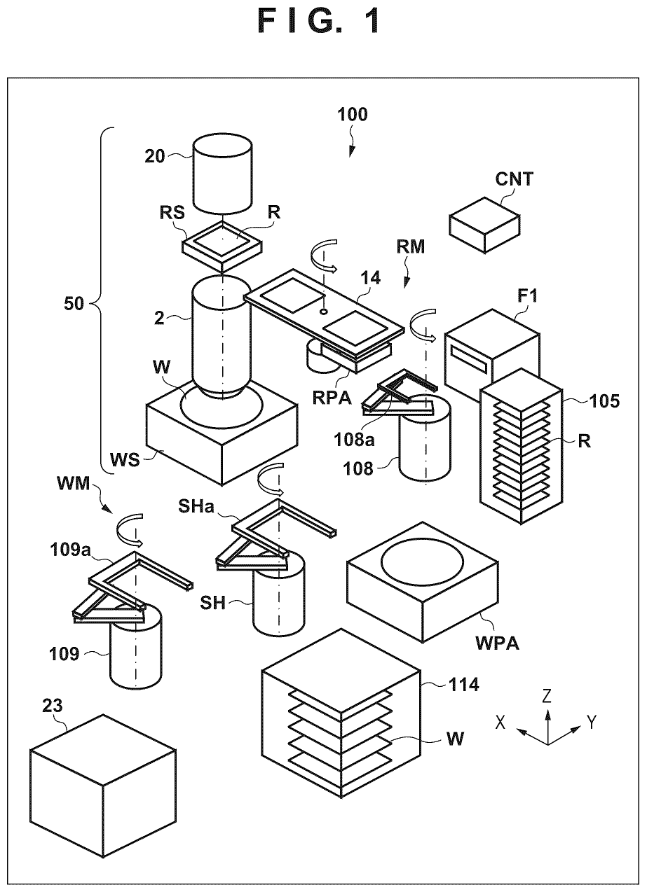

FIG. 1 is a schematic diagram of an exposure apparatus 100 according to an embodiment. In the present description and the drawings, directions are indicated in an XYZ coordinate system where a horizontal plane is an XY plane. In general, a substrate W, which is a target object to be exposed, is placed on a substrate stage WS such that the surface thereof is parallel to the horizontal plane (XY plane). Therefore, in the following description, directions orthogonal to each other in a plane along the surface of the substrate W are defined as an X axis and a Y axis, and a direction perpendicular to the X axis and the Y axis is defined as a Z axis. Hereinafter, directions parallel to the X axis, the Y axis, and the Z axis in the XYZ coordinate system are called an X direction, a Y direction, and a Z direction, respectively, and a rotational direction around the X axis, a rotational direction around the Y axis, and a rotational direction around the Z axis are called a θX direction, a θY direction, and a θZ direction, respectively.

The exposure apparatus 100 is a projection exposure apparatus that exposes (transfers), onto the substrate W (wafer), an image of a pattern formed on an original R (reticle or mask) by a step-and-scan method, for example. The exposure apparatus 100 may be an exposure apparatus of a step-and-repeat method instead of the step-and-scan method.

The exposure apparatus 100 is configured to include a transfer unit 50 that projects and exposes, onto the substrate W, a pattern (e.g., a circuit pattern) formed on the original R, thereby transferring the pattern to the substrate W. The transfer unit 50 can include an original stage RS, an illumination optical system 20, a projection optical system 2, and the substrate stage WS. The original stage RS holds the original R and is driven at least in the Y direction. The original R on the original stage RS is illuminated via the illumination optical system 20 by light emitted from an excimer laser light source, for example. By this, the pattern on the original R is projected on the substrate W at a predetermined magnification by the projection optical system 2. The substrate W is held by the substrate stage WS including a drive shaft extending at least in the X direction and the Y direction.

The exposure apparatus 100 includes an original conveyance mechanism RM that conveys the original R and a substrate conveyance mechanism WM that conveys the substrate W. The substrate conveyance mechanism WM includes a first substrate conveyance robot 109 and a second substrate conveyance robot SH.

The first substrate conveyance robot 109 uses a robot hand 109a to convey a substrate between a substrate relay unit 23 and a substrate pre-alignment stage WPA. The first substrate conveyance robot 109 can be further configured to enable conveyance of the substrate between the substrate relay unit 23 and the substrate stage WS. The substrate relay unit 23 is a buffer apparatus that relays the substrate to and from a coater/developer (not illustrated) present outside the exposure apparatus 100. The substrate pre-alignment stage WPA performs rough alignment with respect to a translation direction (XY direction) and a rotational direction (θZ direction) of the substrate.

The second substrate conveyance robot SH uses a robot hand SHa to convey the substrate among a substrate stocker 114 (substrate storage), the substrate pre-alignment stage WPA, and the substrate stage WS. The substrate stocker 114 can have a shelf-like structure so that a plurality of substrates can be stored. The substrate stocker 114 may be a FOUP or a carrier detachable from the exposure apparatus 100.

The original conveyance mechanism RM can include an original conveyance robot 108 and a rotary hand 14. The original conveyance robot 108 conveys the original among an original pod not illustrated, an original stocker 105 (original storage), and an original pre-alignment stage RPA. The original stocker 105 has a shelf-like structure so that a plurality of originals can be stored. The original pre-alignment stage RPA performs rough alignment with respect to the translation direction (XY direction) and the rotational direction (θZ direction) of the original. As an option, the original conveyance robot 108 may be further configured to convey the original to a foreign substance inspection apparatus FI that inspects a foreign substance on the surface of the original. In this case, the original conveyance robot 108 extracts and conveys, to the foreign substance inspection apparatus FI, the original to be exposed next from the original stocker 105. After the inspection is completed by the foreign substance inspection apparatus FI, the original conveyance robot 108 carried out the original from the foreign substance inspection apparatus FI and places the original on the original pre-alignment stage RPA. In the original pre-alignment stage RPA, the original is aligned with respect to the translation direction (XY direction) and the rotational direction (θZ direction) so as to have a predetermined deviation amount or less with respect to an alignment reference not illustrated (pre-alignment). After completion of the pre-alignment, the exposure apparatus 100 is brought into an exposure standby state.

The rotary hand 14 constitutes a part of the original conveyance mechanism for conveying the original R between the original stage RS and the original stocker 105 or the foreign substance inspection apparatus FI. Upon completion of the exposure of the original R conveyed to an exposure position on the original stage RS, the original stage RS moves to a transfer position with the rotary hand 14, and transfers the original R with exposure complete to the rotary hand 14. Meanwhile, the rotary hand 14 receives the original that has been placed on the original pre-alignment stage RPA and brought into the exposure standby state. At this time, both the original R with exposure complete and the original on standby for exposure are in a state of being placed on the rotary hand 14. In this state, the rotary hand 14 is rotationally driven, and transfers the original R with exposure complete to the original pre-alignment stage RPA and transfers the original on standby for exposure to the original stage RS. Hereinafter, this processing is also called “original exchange”.

The original R with exposure complete is transferred to the original conveyance robot 108, and is conveyed to the original stocker 105 if the original R is scheduled to be used for exposure again later and temporarily stored. If this original R is not scheduled to be used for exposure again, it may be stored in the original pod not illustrated.

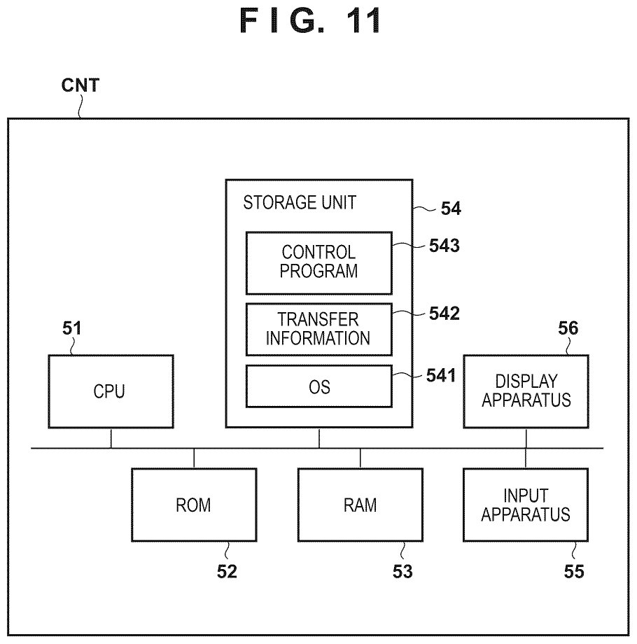

The exposure apparatus 100 includes a controller CNT that controls the operation of each unit of the apparatus. The controller CNT includes, for example, a general-purpose or dedicated computer (information processing apparatus) with a built-in program, and comprehensively controls each unit of the apparatus in accordance with the program. The controller CNT can function as an information processing apparatus that creates a transfer process schedule in a job. FIG. 11 illustrates a configuration example of the controller CNT. The controller CNT can include, for example, a CPU 51, which is a central processing unit, a ROM 52, which holds a boot program and fixed data, and a RAM 53 as a primary storage apparatus that provides a work area of the CPU 51 and holds temporary data. The controller CNT can include a storage unit 54 as a secondary storage apparatus that can include an HDD or an SSD. The storage unit 54 can store an OS 541, transfer information 542 including setting information of exposure processing (transfer process), a control program 543 for performing a transfer process, and the like. Furthermore, an input apparatus 55 such as a keyboard and a mouse that can be operated by the user and a display apparatus 56 that displays various types of information and a GUI are connected to the controller CNT. The user can perform an operation for inputting an exposure job via the GUI provided by the display apparatus 56 or using the input apparatus 55.

Note that the function of the controller CNT may be implemented not by execution of software (program) but by dedicated hardware. For example, the function of the controller CNT can be implemented by a PLD such as an FPGA or an ASIC. The function of the controller CNT may be implemented by a server computer or the like connected to the exposure apparatus 100 via a network or the like.

In the present embodiment, the exposure apparatus 100 is configured to be able to execute a job (exposure job) of performing pattern transfer on one or more substrates having a plurality of shot regions to which a pattern is to be transferred using one or more originals. The controller CNT can perform processing of determining a transfer procedure that can complete an exposure job at maximum speed based on the transfer information 542 including designation of the number of a plurality of originals and the number of a plurality of substrates. The transfer information 542 can include, for example, the following information as information of the apparatus to be used in an exposure job having been input.
Number of originals to be used,
Time required for exchange of the original between the original pre-alignment stage RPA and the original stage RS using the rotary hand 14 (original exchange time),
Time required to convey the original from the original stocker 105 to the original pre-alignment stage RPA (original conveyance time),
Number of substrates to be used (number of substrates to be processed),
Time from when the substrate is carried in from an external coater/developer until the substrate is mounted on the second substrate conveyance robot SH (first substrate conveyance time), and
Time until the substrate from the substrate stocker 114 is mounted on the second substrate conveyance robot SH (second substrate conveyance time).

The transfer information 542 may further include information of a mark to be used that can affect the transfer process step, whether or not to perform foreign substance inspection on the original to be used, a foreign substance inspection time, the number of shot regions to be exposed, an alignment processing time, and a calibration time.

The control program 543 can include a program for executing a plurality of transfer process methods in which the processing order of a plurality of shot regions on the substrate is different from each other or various transfer process methods as described later. Any of the plurality of transfer process methods can be selected based on the number of originals to be used in the transfer process after mounting the substrate once, the number of times of conveyance to the substrate stocker 114, a substrate conveyance path, and the like.

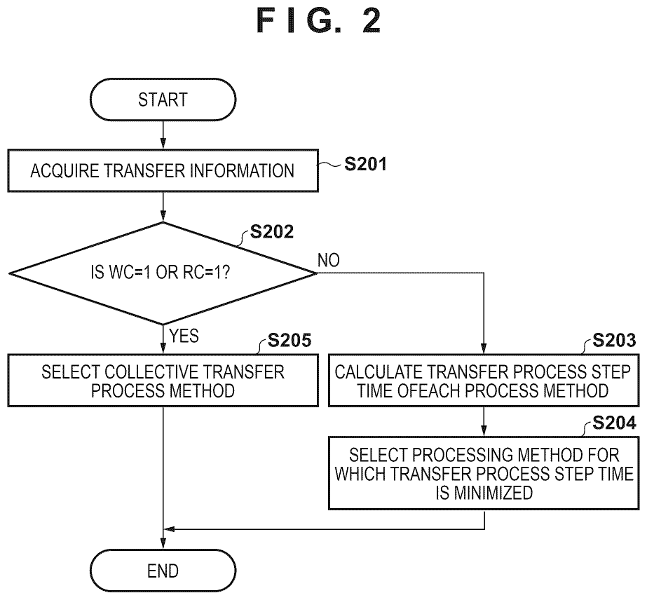

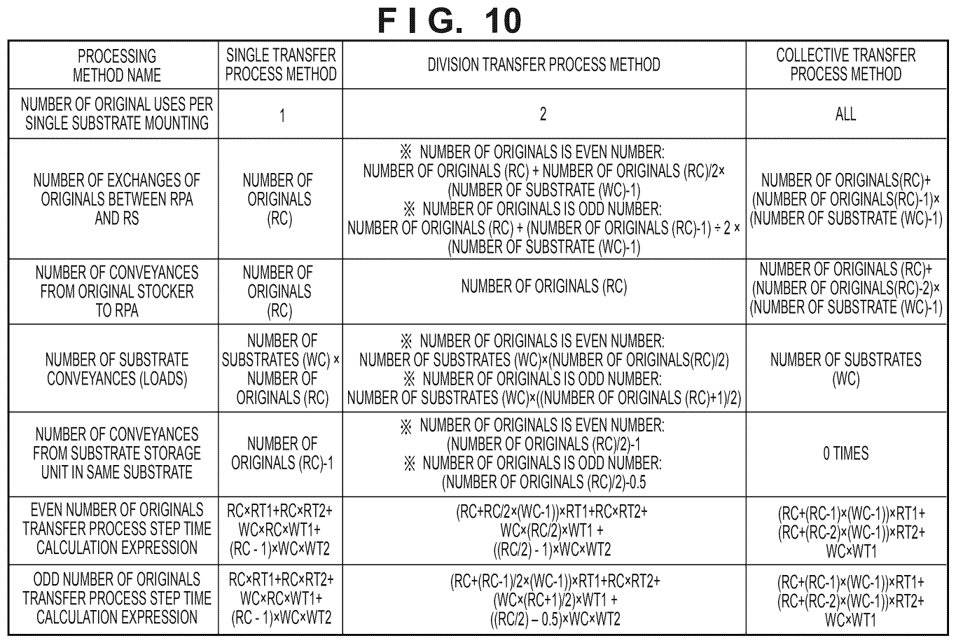

FIG. 2 is a flowchart of processing for determining a transfer process method to be used. FIG. 10 shows the number of times of execution of conveyance of the original and the substrate in each unit and the like, and an expression for calculating the time required for the transfer process step derived based on these, for each of the plurality of transfer process methods (a plurality of transfer procedures). In FIG. 10, examples of transfer process methods that can be selected include the single transfer process method, the division transfer process method, and the collective transfer process method. The content of each of these transfer process methods will be described later.

The following transfer information is used as an expression for calculating the time required for the transfer process step shown in FIG. 10.
Original exchange time RT1: Time required for exchange of the original between the original pre-alignment stage RPA and the original stage RS using the rotary hand 14,
Original conveyance time RT2: Time required to convey the original from the original stocker 105 to the original pre-alignment stage RPA,
First substrate conveyance time WT1: Time from when the substrate is carried in from an external coater/developer until the substrate is mounted on the second substrate conveyance robot SH,
Second substrate conveyance time WT2: Time until the substrate from the substrate stocker 114 is mounted on the second substrate conveyance robot SH,
Number RC of originals to be used, and
Number WC of substrates to be used.

When the job is input, in S201, the controller CNT acquires transfer information to be used in the job. In S202, the controller CNT confirms the number WC of substrates to be used and the number RC of originals to be used. When the number WC of substrates to be used is one, or the number RC of originals to be used is one, the collective transfer process method (described later) is the processing that can minimize the transfer process step time, the controller CNT determines in S205 the collective transfer process method as a transfer process method to be used (S205). When the number WC of substrates to be used is two or more and the number RC of originals to be used is two or more, the processing proceeds to S203. In S203, the controller CNT applies the transfer information acquired in S201 to the calculation expression of each transfer process method shown in FIG. 10 to calculate the transfer process step time for each transfer process method. Note that as shown in FIG. 10, since the calculation expressions are different between the case where the number of originals to be used is an even number and the case where the number of originals to be used is an odd number, the controller CNT determines whether the number WC of substrates to be used is an even number or an odd number, and determines the calculation expression to be applied according to the result. The calculation expression for each transfer process method in FIG. 10 may be individually provided for each number of originals to be used for performing the transfer process. For the calculation, the designation of whether or not to perform foreign substance inspection on the original to be used in the job, the arrangement information of the original to be used, and each processing time included in the transfer information may be changed based on a past conveyance time, a processing condition of the job, and a condition that enables parallel processing. That can improve the calculation accuracy of the transfer process step time.

In S204, based on the calculation result in S203, the controller CNT determines, as a transfer process method to be used, the transfer process method that minimizes the transfer process step time.

Note that the number WC of substrates to be used to be acquired in S201 of FIG. 2 can be selected for all or some of the plurality of substrates existing in the coater/developer. This can designate the number of substrates to be used in a case where the number of substrates to be carried out from the coater/developer is limited or in accordance with the number of substrates that can be accommodated in the substrate stocker 114. For example, when there are 25 substrates in the coater/developer, the number WC of substrates to be used can be designated to 15. In that case, in accordance with the flowchart of FIG. 2, the controller CNT calculates the transfer process step time of each transfer process method with WC=15, and determines the transfer process method to be used. Thereafter, for the remaining ten substrates among the 25 substrates in the coater/developer, in accordance with the flowchart of FIG. 2, the controller CNT calculates the transfer process step time of each transfer process method with WC=15, and determines the transfer process method to be used.

Hereinafter, specific examples of processing for determining the transfer process method will be described.

### Example 1

A case where the following transfer information is given in S201 will be considered.
Original exchange time RT1=10 seconds,
Original conveyance time RT2=30 seconds,
First substrate conveyance time WT1=5 seconds,
Second substrate conveyance time WT2=30 seconds,
Number RC of originals to be used=4,
Number WC of substrates to be used=25

When the transfer information described above is applied to the calculation expressions of the transfer process methods shown in FIG. 10 (S203), calculation results of 2910 seconds for the single transfer process method, 1640 seconds for the division transfer process method, and 2445 seconds for the collective transfer process method are derived. The controller CNT determines the division transfer process method with the shortest transfer process step time as a transfer process method to be used (S204).

### Example 2

A case where the following transfer information is given in S201 will be considered.
Original exchange time RT1=20 seconds,
Original conveyance time RT2=30 seconds,
First substrate conveyance time WT1=5 seconds,
Second substrate conveyance time WT2=10 seconds,
Number RC of originals to be used=4,
Number WC of substrates to be used=25

When the transfer information described above is applied to the calculation expressions of the transfer process methods shown in FIG. 10 (S203), calculation results of 1450 seconds for the single transfer process method, 1660 seconds for the division transfer process method, and 3205 seconds for the collective transfer process method are derived. The controller CNT determines the single transfer process method with the shortest transfer process step time as a transfer process method to be used (S204).

Hereinafter, specific examples of the plurality of transfer process methods will be described. In the present embodiment, the plurality of transfer process methods can include the collective transfer process method, the division transfer process method, and the single transfer method as also shown in FIG. 10.

### Collective Transfer Process Method

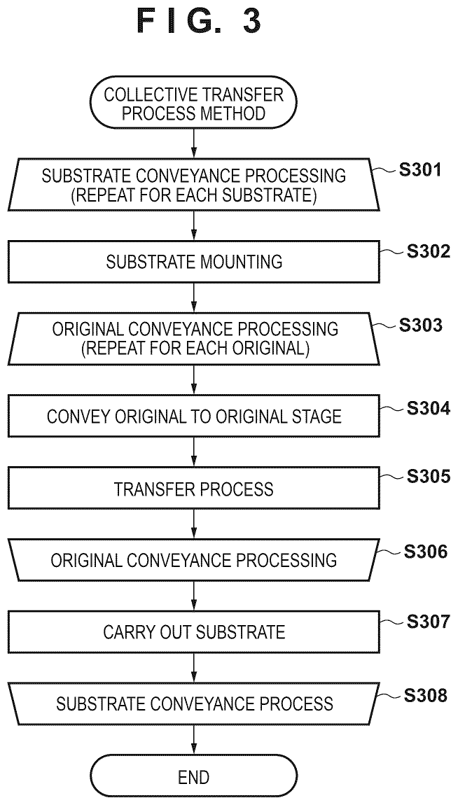

The collective transfer process method (first procedure) is a method of repeating, for each of the substrates to be used, performing pattern transfer on the plurality of shot regions while sequentially exchanging all of the originals to be used without exchanging the substrate midway with respect to one substrate. FIG. 3 is a flowchart of the collective transfer process method. In the collective transfer process method, the following repetitive processing is performed for each substrate conveyance processing in which one substrate is conveyed to the substrate stage WS (S301 to S308). The end condition of the repetitive processing is that the number of times of the substrate conveyance processing reaches the number WC of substrates to be used.

In S302, the controller CNT controls the second substrate conveyance robot SH to convey the substrate to the substrate stage WS.

Next, the following repetitive processing is performed for each original conveyance processing in which one original is conveyed to the original stage RS (S303 to S306). The end condition of the repetitive processing is that the number of times of the original conveyance processing reaches the number RC of originals to be used.

In S304, the controller CNT controls the original conveyance robot 108 to convey the original to be used from the original stocker 105 to the original pre-alignment stage RPA. In a case of an option of performing foreign substance inspection, the original is conveyed to the foreign substance inspection apparatus FI, and then conveyed to the original pre-alignment stage RPA. After the pre-alignment is performed on the original pre-alignment stage RPA, the original is conveyed to the original stage RS via the rotary hand 14. At this time, if there is an original after completion of exposure on the original stage RS, the original exchange is performed, and the original after completion of exposure is stored in the original stocker 105 by the original conveyance robot 108. If there is an original to be used next, the controller CNT controls the original conveyance robot 108 to extract the original from the original stocker 105 and convey the original to the original pre-alignment stage RPA. In a case of an option of performing foreign substance inspection, the original is conveyed to the foreign substance inspection apparatus FI, and then conveyed to the original pre-alignment stage RPA. When the pre-alignment is performed on the original pre-alignment stage RPA, the exposure apparatus 100 is brought into an exposure standby state.

In S305, the controller CNT controls the transfer unit 50 to transfer the pattern of the original on the original stage RS to the substrate on the substrate stage WS.

In S306, the controller CNT determines whether the transfer has ended using all the originals to be used. If an unprocessed original still remains, the processing returns to S304, and a transfer process using a new original is performed. After the transfer process using all the originals is completed with respect to one substrate, the controller CNT carries out the substrate in S307. That is, the controller CNT conveys the substrate to the substrate relay unit 23 in order to transfer the substrate to the coater/developer.

In S308, the controller CNT determines whether the transfer process on all the substrates has been completed. If an unprocessed substrate still remains, the processing returns to S302, and a transfer process on a new substrate is performed.

In the collective transfer process method, the number of times of carrying out the original from the original stocker 105 and the number of times of original exchange increase as the number RC of originals to be used increases or the number WC of substrates to be used increases, and therefore the transfer process step time increases. On the other hand, when the number RC of originals to be used is one or the number WC of substrates to be used is one, the transfer process step time is shorter than that in the division transfer process method and the single transfer process method. The collective transfer process method is characterized by not carrying out the substrate from the substrate stocker 114. That is, the substrate stocker 114 is not used in the collective transfer process method. Therefore, the longer the time required for conveying the substrate from the substrate stocker 114 is, the shorter the transfer process step time becomes as compared with the division transfer process method and the single transfer method.

### Division Transfer Process Method

The division transfer process method (second procedure) is a method of dividing a plurality of originals into a plurality of sets, and exchanging substrates of the transfer target (substrates to be held by the substrate stage WS) in units of sets of the originals. Specifically, pattern transfer is executed using the first set of originals with respect to some of the plurality of shot regions of the first substrate, and the first substrate is temporarily stored in the substrate stocker 114. Thereafter, pattern transfer using the first set of originals and storage of the substrate into the substrate stocker 114 are repeatedly executed with respect to the some of the plurality of shot regions of the second substrate and each subsequent substrate. Next, the first substrate is extracted from the substrate stocker 114 and conveyed to the substrate stage WS, and pattern transfer using the second set of originals with respect to the other shot regions of the first substrate and storage of the first substrate in the substrate stocker 114 (or carry-out to the outside) are executed. Thereafter, pattern transfer using the second set of originals and storage of the substrate in the substrate stocker 114 (or carry-out to the outside) are repeatedly executed with respect to other shot regions of the substrate of the second substrate and subsequent substrates.

For example, when the number RC of originals to be used is four, the originals are divided into two sets of two, pattern transfer is executed using the first set of originals with respect to the first substrate, and the first substrate is stored in the substrate stocker 114. Next, pattern transfer is executed using the second set of originals with respect to the second substrate, and the second substrate is stored in the substrate stocker 114. Thereafter, the first substrate is extracted from the substrate stocker 114 and conveyed to the substrate stage WS, and pattern transfer using the second set of originals with respect to the first substrate and storage of the substrate of the first substrate in the substrate stocker 114 (or carry-out to the outside) are executed. Thereafter, the first substrate is extracted from the substrate stocker 114 and conveyed to the substrate stage WS, and pattern transfer using the second set of originals with respect to the first substrate and storage of the substrate of the first substrate in the substrate stocker 114 (or carry-out to the outside) are executed.

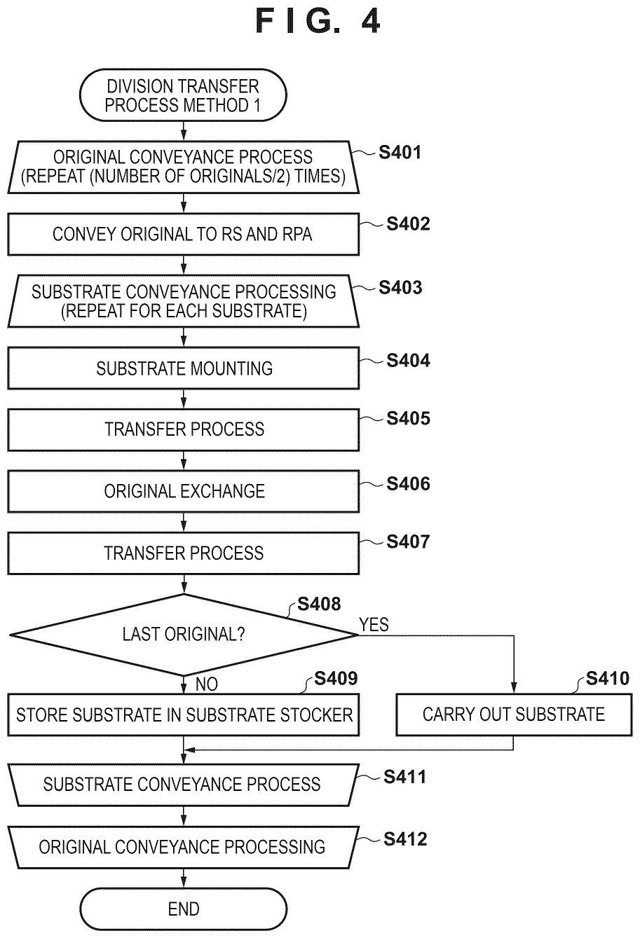

FIG. 4 is a flowchart of the division transfer process method in a case where the number of originals to be used is an even number. In the division transfer process method, the following repetitive processing is performed for each original conveyance processing in which one original is conveyed to the original stage RS (S401 to S412). When the number of originals to be used is an even number, the end condition of the repetitive processing is that the number of times of the original conveyance processing reaches (the number RC of originals to be used)/2. Note that this “/2” is a value when the number of the original pre-alignment stage RPA is one.

In S402, the original is conveyed to the original stage RS and the original pre-alignment stage RPA. Specifically, the controller CNT controls the original conveyance robot 108 to extract the original from the original stocker 105 and convey the original to the original pre-alignment stage RPA. In the case of an option of performing foreign substance inspection, the original is conveyed to the foreign substance inspection apparatus FI, and then conveyed to the original pre-alignment stage RPA. After the pre-alignment is performed on the original pre-alignment stage RPA, the original is conveyed to the original stage RS via the rotary hand 14. At this time, if there is an original after completion of exposure on the original stage RS, the original exchange is performed, and the original after completion of exposure is stored in the original stocker 105 by the original conveyance robot 108. Next, the controller CNT controls the original conveyance robot 108 to extract the original from the original stocker 105 and convey the original to the original pre-alignment stage RPA. In the case of an option of performing foreign substance inspection, the original is conveyed to the foreign substance inspection apparatus FI, and then conveyed to the original pre-alignment stage RPA. When the pre-alignment is performed on the original pre-alignment stage RPA, the exposure apparatus 100 is brought into an exposure standby state. Thus, the conveyance of the original to the original stage RS and the original pre-alignment stage RPA is completed.

Next, the following repetitive processing is performed for each substrate conveyance processing in which one substrate is conveyed to the substrate stage WS (S403 to S411). The end condition of the repetitive processing is that the number of times of the substrate conveyance processing reaches the number WC of substrates to be used.

In S404, the controller CNT controls the first substrate conveyance robot 109 and the second substrate conveyance robot SH to convey the substrate to the substrate stage WS.

In S405, the controller CNT controls the transfer unit 50 to transfer the pattern of the original on the original stage RS to the substrate on the substrate stage WS.

In S406, the controller CNT controls the rotary hand 14 and the original stage RS to perform original exchange. By this, the original on the original pre-alignment stage RPA is conveyed onto the original stage RS. After the exposure (transfer) ends, the original conveyed from the original stage RS to the original pre-alignment stage RPA by the original exchange is stored in the original stocker 105 by the original conveyance robot 108.

In S407, the controller CNT controls the transfer unit 50 to transfer the pattern of the original on the original stage RS to the substrate on the substrate stage WS.

In S408, the controller CNT confirms whether the processing has been completed up to the last original. If the processing has not ended up to the last original, the controller CNT controls in S409 the first substrate conveyance robot 109 and the second substrate conveyance robot SH to convey the substrate on the substrate stage WS to the substrate stocker 114. On the other hand, if the processing has ended up to the last original, the controller CNT controls in S410 the first substrate conveyance robot 109 and the second substrate conveyance robot SH to convey the substrate on the substrate stage WS to the substrate relay unit 23 so as to be passed to the coater/developer.

By the processing loop of S403 to S411 described above, pattern transfer using the first set of originals is first performed with respect to the first substrate. At this time, in S404, the first substrate conveyance robot 109 and the second substrate conveyance robot SH convey the first substrate from the substrate relay unit 23 to the substrate stage WS. In the processing of S403 to S411 to be performed next, pattern transfer using the first set of originals is performed with respect to the second substrate. At this time, in S404, the first substrate conveyance robot 109 and the second substrate conveyance robot SH convey the second substrate from the substrate relay unit 23 to the substrate stage WS. In this manner, pattern transfer using the first set of originals is performed with respect to all the substrates, and each substrate is stored in the substrate stocker 114.

In step S402 to be performed next, the original to be used is exchanged from the first set of originals to the second set of originals. Thereafter, pattern transfer using the second set of originals is performed with respect to the first substrate by the processing of S403 to S411. At this time, in S404, the first substrate conveyance robot 109 and the second substrate conveyance robot SH convey the first substrate from the substrate stocker 114 to the substrate stage WS. In the processing of S403 to S411 to be performed next, pattern transfer using the second set of originals is performed with respect to the second substrate. At this time, in S404, the first substrate conveyance robot 109 and the second substrate conveyance robot SH convey the second substrate from the substrate stocker 114 to the substrate stage WS. In this manner, pattern transfer using the second set of originals is performed with respect to all the substrates. If the second set of originals is the last original, each substrate is carried out to the coater/developer via the substrate relay unit 23 (S410).

In the division transfer process method in a case where the number of originals to be used is an even number, since the number of times of the repetitive processing for each original conveyance processing is (the number RC of originals to be used)/2 times, the number of times of conveying the original from the original stocker 105 is reduced as compared with the single transfer process method and the collective transfer process method. Therefore, the longer the time required for conveying the original, the shorter the transfer process step time becomes as compared with the single transfer process method and the collective transfer process method.

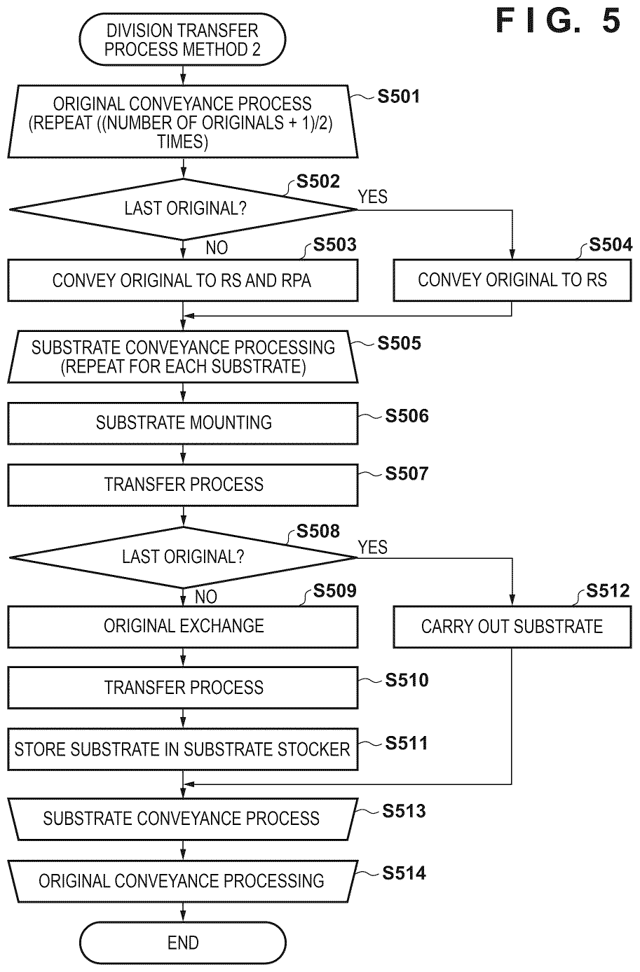

FIG. 5 is an example of a flowchart of the division transfer process method in a case where the number of originals to be used is an odd number. In the division transfer process method, the following repetitive processing is performed for each original conveyance processing in which one original is conveyed to the original stage RS (S501 to S514). When the number of originals to be used is an odd number, the end condition of the repetitive processing is that the number of times of the original conveyance processing reaches ((the number RC of originals to be used)+1)/2. Note that this “/2” is a value when the number of the original pre-alignment stage RPA is one.

In S502, the controller CNT confirms whether or not the original of a processing target is the last original.

If the original of the processing target is not the last original, the conveyance of the original to the original stage RS and the original pre-alignment stage RPA is performed in S503. Specifically, the controller CNT controls the original conveyance robot 108 to extract the original from the original stocker 105, and conveys the original to the original pre-alignment stage RPA (through the foreign substance inspection apparatus FI in the case of an option of performing foreign substance inspection). After the pre-alignment is performed on the original pre-alignment stage RPA, the original is conveyed to the original stage RS via the rotary hand 14. At this time, if there is an original after completion of exposure on the original stage RS, the original exchange is performed, and the original after completion of exposure is stored in the original stocker 105 by the original conveyance robot 108. Next, the controller CNT controls the original conveyance robot 108 to extract the original from the original stocker 105, and conveys the original (via the foreign substance inspection apparatus FI in the case of an option of performing foreign substance inspection) to the original pre-alignment stage RPA. When the pre-alignment is performed on the original pre-alignment stage RPA, the exposure apparatus 100 is brought into an exposure standby state. Thus, the conveyance of the original to the original stage RS and the original pre-alignment stage RPA is completed.

If the original of the processing target is the last original, the controller CNT conveys in S504 the original in the exposure standby state on the original pre-alignment stage RPA to the original stage RS via the rotary hand 14. Here, since the original in the exposure standby state on the original pre-alignment stage RPA is the last original, there is no work of extracting the original from the original stocker 105.

Next, the following repetitive processing is performed for each substrate conveyance processing in which one substrate is conveyed to the substrate stage WS (S505 to S513). The end condition of the repetitive processing is that the number of times of the substrate conveyance processing reaches the number WC of substrates to be used.

In S506, the controller CNT controls the second substrate conveyance robot SH to convey the substrate to the substrate stage WS.

In S507, the controller CNT controls the transfer unit 50 to transfer the pattern of the original on the original stage RS to the substrate on the substrate stage WS.

In S508, the controller CNT confirms whether the processing has been completed up to the last original. If the processing has ended up to the last original, the controller CNT controls in S512 the first substrate conveyance robot 109 and the second substrate conveyance robot SH to convey the substrate on the substrate stage WS to the substrate relay unit 23 so as to be passed to the coater/developer. On the other hand, if the processing has not ended up to the last original, the processing proceeds to S509.

In S509, the controller CNT controls the rotary hand 14 and the original stage RS to perform original exchange. By this, the original on the original pre-alignment stage RPA is conveyed onto the original stage RS.

In S510, the controller CNT controls the transfer unit 50 to transfer the pattern of the original on the original stage RS to the substrate on the substrate stage WS.

In S511, the controller CNT controls the first substrate conveyance robot 109 and the second substrate conveyance robot SH to convey the substrate on the substrate stage WS to the substrate stocker 114.

By the processing loop of S505 to S513 described above, pattern transfer using the first set of originals is first performed with respect to the first substrate. At this time, in S506, the first substrate conveyance robot 109 and the second substrate conveyance robot SH convey the first substrate from the substrate relay unit 23 to the substrate stage WS. In the processing of S505 to S513 to be performed next, pattern transfer using the first set of originals is performed with respect to the second substrate. At this time, in S506, the first substrate conveyance robot 109 and the second substrate conveyance robot SH convey the second substrate from the substrate relay unit 23 to the substrate stage WS. In this manner, pattern transfer using the first set of originals is performed with respect to all the substrates, and each substrate is stored in the substrate stocker 114.

In S503 or S504 to be performed next, the original to be used is exchanged from the first set of originals to the second set of originals. Thereafter, pattern transfer using the second set of originals is performed with respect to the first substrate by the processing of S505 to S513. At this time, in S506, the first substrate conveyance robot 109 and the second substrate conveyance robot SH convey the first substrate from the substrate stocker 114 to the substrate stage WS. In the processing of S505 to S513 to be performed next, pattern transfer using the second set of originals is performed with respect to the second substrate. At this time, in S506, the first substrate conveyance robot 109 and the second substrate conveyance robot SH convey the second substrate from the substrate stocker 114 to the substrate stage WS. In this manner, pattern transfer using the second set of originals is performed with respect to all the substrates. If the second set of originals is the last original, each substrate is carried out to the coater/developer via the substrate relay unit 23 (S512).

In the division transfer process method in a case where the number of originals to be used is an odd number, since the number of times of the repetitive processing for each original conveyance processing is ((the number RC of originals to be used)+1)/2 times, the number of times of conveying the original from the original stocker 105 is reduced as compared with the single transfer process method and the collective transfer process method. Therefore, the longer the time required for conveying the original, the shorter the transfer process step time becomes as compared with the single transfer process method and the collective transfer process method.

Note that “/2” used in the end condition of the repetitive processing in S401 of FIG. 4 and S501 of FIG. 5 is a value when the number of the original pre-alignment stage RPA is one as described above. This value fluctuates depending on the number of originals that can be held around the original stage RS. For example, in a case where three original pre-alignment stages RPA are arranged, the number of originals that can be held by the original stage RS and the three original pre-alignment stages RPA is four, and therefore the value is “/4”. In a case where two original pre-alignment stages RPA are arranged, the number of originals that can be held by the original stage RS and the two original pre-alignment stages RPA is three, and therefore the value is “/3”. The calculation expression of the number of times of each process and the transfer process step time in the division transfer process method of FIG. 10 similarly fluctuates depending on the number of originals that can be held around the original stage RS.

### Single Transfer Process Method

The single transfer process method (third procedure) is a method of repeating, for each of the originals to be used, performing pattern transfer on some of the plurality of shot regions while sequentially exchanging all of the substrates to be used without exchanging the original midway with respect to one original.

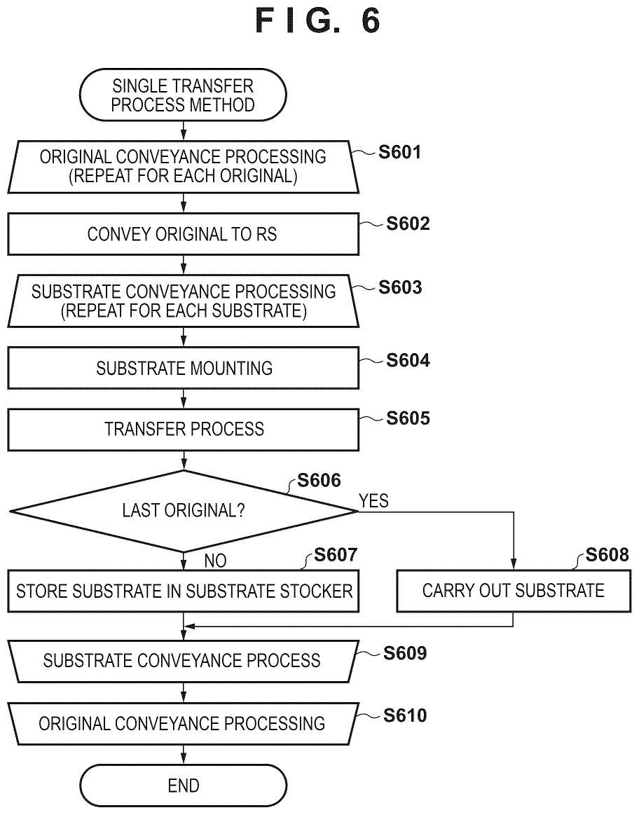

FIG. 6 is a flowchart of the single transfer process method. In the single transfer process method, the following repetitive processing is performed for each original conveyance processing in which one original is conveyed to the original stage RS (S601 to S610). The end condition of the repetitive processing is that the number of times of the original conveyance processing reaches the number RC of originals to be used.

In step S602, the conveyance of the original to the original stage RS is performed. Specifically, the controller CNT controls the original conveyance robot 108 to extract the original from the original stocker 105, and conveys the original to the original pre-alignment stage RPA (through the foreign substance inspection apparatus FI in the case of an option of performing foreign substance inspection). After the pre-alignment is performed on the original pre-alignment stage RPA, the original is conveyed to the original stage RS via the rotary hand 14. At this time, if there is an original after completion of exposure on the original stage RS, the original exchange is performed, and the original after completion of exposure is stored in the original stocker 105 by the original conveyance robot 108. Next, the controller CNT controls the original conveyance robot 108 to extract the original from the original stocker 105, and conveys the original (via the foreign substance inspection apparatus FI in the case of an option of performing foreign substance inspection) to the original pre-alignment stage RPA. When the pre-alignment is performed on the original pre-alignment stage RPA, the exposure apparatus 100 is brought into an exposure standby state. Thus, the conveyance of the original to the original stage RS and the original pre-alignment stage RPA is completed.

Next, the following repetitive processing is performed for each substrate conveyance processing in which one substrate is conveyed to the substrate stage WS (S603 to S609). The end condition of the repetitive processing is that the number of times of the substrate conveyance processing reaches the number WC of substrates to be used.

In S604, the controller CNT controls the second substrate conveyance robot SH to convey the substrate to the substrate stage WS.

In S605, the controller CNT controls the transfer unit 50 to transfer the pattern of the original on the original stage RS to the substrate on the substrate stage WS.

In S606, the controller CNT confirms whether the processing has been completed up to the last original. If the processing has not ended up to the last original, the controller CNT controls in S607 the first substrate conveyance robot 109 and the second substrate conveyance robot SH to convey the substrate on the substrate stage WS to the substrate stocker 114. On the other hand, if the processing has ended up to the last original, the controller CNT controls in S608 the first substrate conveyance robot 109 and the second substrate conveyance robot SH to convey the substrate on the substrate stage WS to the substrate relay unit 23 so as to be passed to the coater/developer.

By the processing loop of S603 to S609 described above, a transfer process using the first original is first performed with respect to the first substrate. At this time, in S604, the first substrate conveyance robot 109 and the second substrate conveyance robot SH convey the first substrate from the substrate relay unit 23 to the substrate stage WS. In the processing of S603 to S609 to be performed next, the transfer process using the first original is performed with respect to the second substrate. At this time, in S604, the first substrate conveyance robot 109 and the second substrate conveyance robot SH convey the second substrate from the substrate relay unit 23 to the substrate stage WS. In this manner, the transfer process using the first original is performed with respect to all the substrates, and each substrate is stored in the substrate stocker 114.

In step S602 to be performed next, the original to be used is exchanged from the first original to the second original. Thereafter, by the processing of S603 to S609, a transfer process using the second original is performed with respect to the first substrate. At this time, in S604, the first substrate conveyance robot 109 and the second substrate conveyance robot SH convey the first substrate from the substrate stocker 114 to the substrate stage WS. In the processing of S603 to S609 to be performed next, transfer process using the second original is performed with respect to the second substrate. At this time, in S604, the first substrate conveyance robot 109 and the second substrate conveyance robot SH convey the second substrate from the substrate stocker 114 to the substrate stage WS. In this manner, the transfer process using the second original is performed with respect to all the substrates. If the second original is the last original, each substrate is carried out to the coater/developer via the substrate relay unit 23 (S608).

The single transfer process method can reduce the number of times of original exchange to be performed between the original pre-alignment stage RPA and the original stage RS as compared with other methods. On the other hand, in the single transfer process method, the number of times of conveying the substrate from the substrate stocker 114 increases, but the shorter the time for conveying the substrate from the substrate stocker 114 is, the shorter the transfer process step time becomes as compared with the collective transfer process method and the division transfer process method.

### Time Shortening Effect in Each Transfer Method

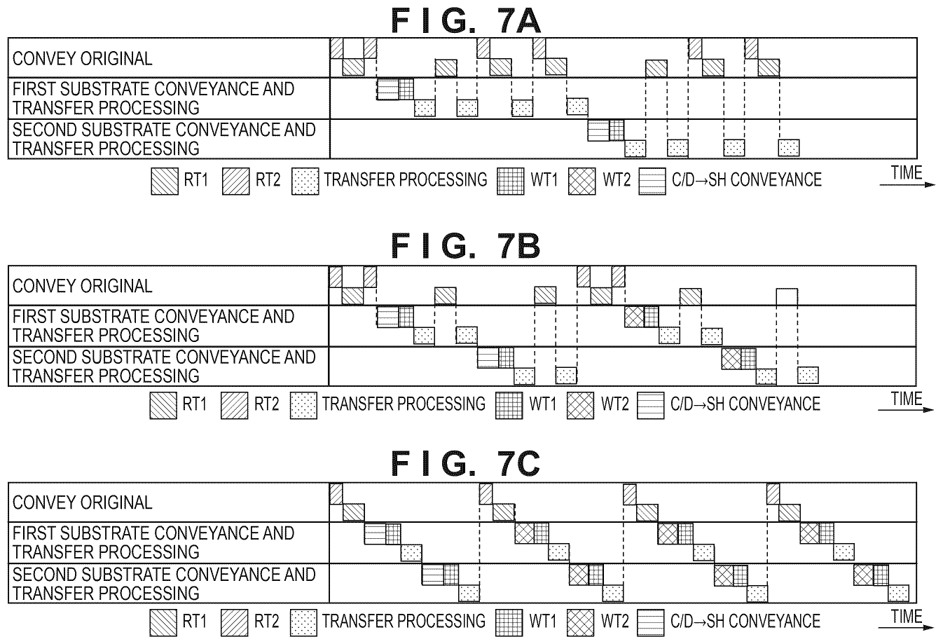

FIGS. 7A to 7C are timing charts of each transfer process method. Here, the number of substrates to be used is two, and the number of originals to be used is four. FIG. 7A is the timing chart of the collective transfer process method, FIG. 7B is the timing chart of the division transfer process method, and FIG. 7C is the timing chart of the single transfer process method. The horizontal axis is a time axis. The meaning of each symbol in the drawing is as follows.
RT1: Time required for original exchange between the original pre-alignment stage RPA and the original stage RS,
RT2: Time required for conveying the original from the original stocker 105 to the original pre-alignment stage RPA,
WT1: Time required for conveying the substrate from the coater/developer (C/D) to the second substrate conveyance robot SH, and
WT2: Time required for conveying the substrate from the substrate stocker 114 to the second substrate conveyance robot SH.

According to FIGS. 7A to 7C, it is known that the time of the transfer process step by the collective transfer process method is the shortest.

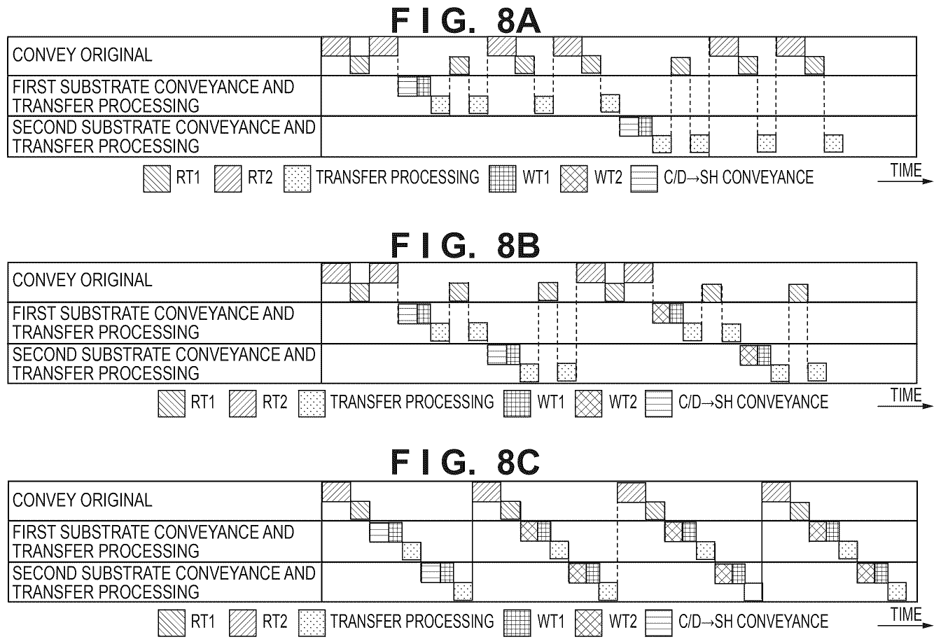

FIGS. 8A to 8C are timing charts in a case where the transfer process is performed under the same transfer conditions as in the case of FIGS. 7A to 7C but the time RT2 required for conveying the original from the original stocker 105 to the original pre-alignment stage RPA is long. According to FIGS. 8A to 8C, it is known that the time of the transfer process step by the division transfer process method is the shortest. That is, when the time RT2 required for conveying the original from the original stocker 105 to the original pre-alignment stage RPA becomes longer, the division transfer process method becomes superior in terms of the transfer process step time.

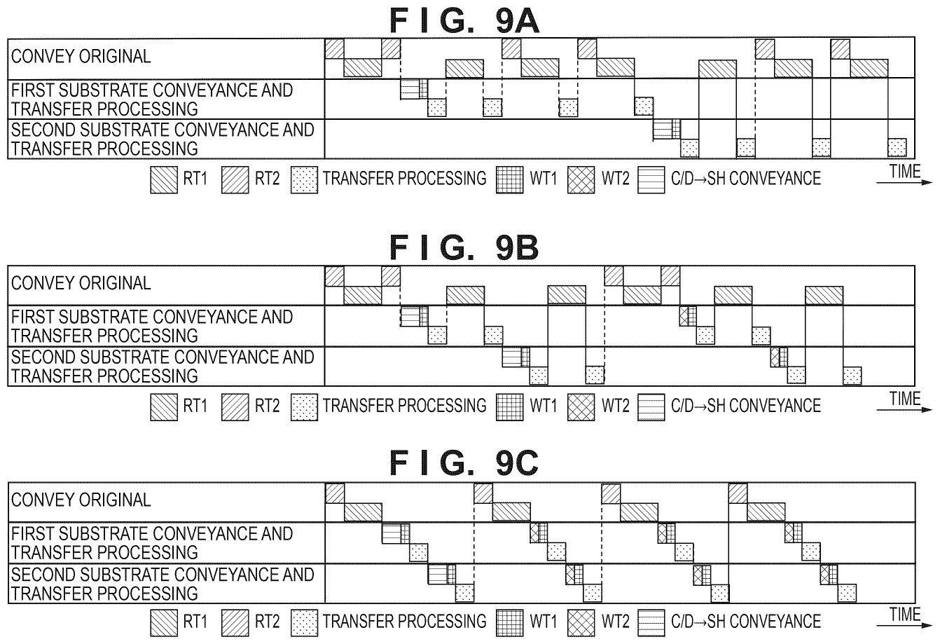

FIGS. 9A to 9C are timing charts in a case where the transfer process is performed under the same transfer conditions as in the cases of FIGS. 7A to 7C and FIGS. 8A to 8C but the time RT1 required for original exchange between the original pre-alignment stage RPA and the original stage RS is long. According to FIGS. 9A to 9C, it is known that the time of the transfer process step by the single transfer process method is the shortest. That is, when the time RT1 required for original exchange between the original pre-alignment stage RPA and the original stage RS becomes longer, the single transfer process method becomes superior in terms of the transfer process step time.

Note that in each transfer process method, the processing of conveying the substrate from the coater/developer to the second substrate conveyance robot SH may be executed in parallel to the processing of performing original exchange between the original pre-alignment stage RPA and the original stage RS. The processing of conveying the substrate from the coater/developer to the second substrate conveyance robot SH may be executed in parallel to the processing of conveying the original from the original stocker 105 to the original stage RS. In that case, a calculation expression of the transfer process step time is derived in consideration of the processing of performing original exchange between the original pre-alignment stage RPA and the original stage RS.

The processing of conveying the substrate from the substrate stocker 114 to the second substrate conveyance robot SH may be executed in parallel to the processing of performing original exchange between the original pre-alignment stage RPA and the original stage RS. The processing of conveying the substrate from the substrate stocker 114 to the second substrate conveyance robot SH may be executed in parallel to the processing of transferring the original from the original stocker 105 to the original stage RS. In that case, a calculation expression of the transfer process step time is derived in consideration of the processing of performing original exchange between the original pre-alignment stage RPA and the original stage RS.

According to the above-described various embodiments, it is possible to improve the productivity of an exposure apparatus that performs exposure processing (transfer process) using a plurality of originals with respect to each substrate.

### Embodiment of Article Manufacturing Method

The article manufacturing method in an embodiment of the present disclosure is suitable, for example, for manufacturing an article such as a microdevice such as a semiconductor device or an element having a microstructure. The article manufacturing method of the present embodiment includes a transfer step of transferring a pattern of an original to a substrate using the lithography apparatus (exposure apparatus, imprint apparatus, and the like) described above, and a processing step of processing the substrate to which the pattern has been transferred in the transfer step. Furthermore, such the manufacturing method includes other well-known processes (oxidation, film formation, vapor deposition, doping, planarization, etching, resist peeling, dicing, bonding, packaging, and the like). The article manufacturing method of the present embodiment is advantageous in at least one of performance, quality, productivity, and production cost of an article as compared with known methods.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-199204, filed Nov. 14, 2024 which is hereby incorporated by reference herein in its entirety.

What is claimed is:

1. A lithography apparatus configured to execute a job of performing pattern transfer on one or more substrates having a plurality of shot regions using one or more originals, the lithography apparatus comprising:
an original stage; and
a controller that determines a transfer procedure that can complete the job at maximum speed based on a number of originals to be used in the job and a number of substrates to be processed.

2. The lithography apparatus according to claim 1, wherein
the controller
calculates a processing time of the job in a case where each of a plurality of transfer procedures is applied, and
selects a transfer procedure that minimizes the calculated processing time among the plurality of transfer procedures.

3. The lithography apparatus according to claim 2 further comprising:
an original conveyance mechanism that conveys an original; and
a substrate conveyance mechanism that conveys a substrate, wherein
the controller determines a transfer procedure that can complete the job at maximum speed based on a time required for the original conveyance mechanism to convey an original and a time required for the substrate conveyance mechanism to convey a substrate.

4. The lithography apparatus according to claim 3 further comprising:
an original storage that stores a plurality of originals; and
an original pre-alignment stage that performs pre-alignment of an original, wherein
the original conveyance mechanism is configured to convey an original among the original storage, the original pre-alignment stage, and the original stage, and
a substrate storage that stores a plurality of substrates,
a substrate pre-alignment stage that performs pre-alignment of a substrate,
a substrate stage that holds, for the pattern transfer, the substrate on which the pre-alignment has been performed in the substrate pre-alignment stage, and
the substrate conveyance mechanism are configured to convey a substrate among an outside, the substrate storage, the substrate pre-alignment stage, and the substrate stage.

5. The lithography apparatus according to claim 4, wherein
the original conveyance mechanism includes
an original conveyance robot that conveys an original between the original storage and the original pre-alignment stage, and
a rotary hand rotationally driven to exchange an original on the original pre-alignment stage and an original on the original stage,
the substrate conveyance mechanism includes
a first substrate conveyance robot that transfers a substrate among an outside, the substrate pre-alignment stage, and the substrate stage, and
a second substrate conveyance robot that transfers a substrate among the substrate storage, the substrate pre-alignment stage, and the substrate stage, and
the controller
determines a transfer procedure that can complete the job at maximum speed based further on
a time required for exchange of an original between the original stage and the original pre-alignment stage by the rotary hand,
a time required for conveyance of an original from the original storage to the original pre-alignment stage by the original conveyance robot,
a time from when a substrate is carried in from an outside until the substrate is mounted on the second substrate conveyance robot, and
a time until the substrate from the substrate storage is mounted on the second substrate conveyance robot.

6. The lithography apparatus according to claim 4, wherein the plurality of transfer procedures include a first procedure of repeating, for each of the substrates to be processed, performing the pattern transfer on the plurality of shot regions while sequentially exchanging all of the originals to be used without exchanging a substrate midway.

7. The lithography apparatus according to claim 6, wherein when a number of the substrate to be processed is one or a number of the original to be used is one, the controller determines the first procedure as a transfer procedure that can complete the job at maximum speed.

8. The lithography apparatus according to claim 6, wherein
the plurality of transfer procedures further include a second procedure of dividing a plurality of originals to be used into a plurality of sets and exchanging a substrate to be held by the substrate stage in units of sets of originals, and
the second procedure includes
executing the pattern transfer using a first set of originals with respect to some of the plurality of shot regions of a first substrate and storing the first substrate into the substrate storage,
repeatedly executing the pattern transfer using the first set of originals and storage of the substrate into the substrate storage with respect to the some shot regions of a second substrate and each subsequent substrate,
executing the pattern transfer using a second set of originals with respect to another shot region of the first substrate extracted from the substrate storage, and storing the first substrate into the substrate storage or carrying out the first substrate to an outside, and
repeatedly executing the pattern transfer using the second set of originals and storage of the substrate into the substrate storage or carrying-out of the substrate to the outside with respect to the other shot region of the second substrate and each subsequent substrate extracted from the substrate storage.

9. The lithography apparatus according to claim 6, wherein the plurality of transfer procedures further include a third procedure of repeating, for each of the originals to be used, performing the pattern transfer on some of the plurality of shot regions while sequentially exchanging all of the substrates to be processed without exchanging an original midway.

10. The lithography apparatus according to claim 5, wherein processing of conveying a substrate carried in from an outside to the second substrate conveyance robot and processing of exchanging an original between the original stage and the original pre-alignment stage by the rotary hand are executed in parallel.

11. The lithography apparatus according to claim 5, wherein processing of transferring a substrate from the substrate storage to the second substrate conveyance robot and processing of exchanging an original between the original stage and the original pre-alignment stage by the rotary hand are executed in parallel.

12. The lithography apparatus according to claim 5, wherein processing of transferring a substrate from the substrate storage to the second substrate conveyance robot and processing of transferring an original from the original storage to the original stage are executed in parallel.

13. The lithography apparatus according to claim 1, wherein the controller determines a transfer procedure that can complete the job at maximum speed based on designation of whether or not to perform foreign substance inspection of an original by the foreign substance inspection apparatus.

14. The lithography apparatus according to claim 1, wherein the lithography apparatus is an exposure apparatus that projects a pattern of the original onto the substrate via a projection optical system to transfer the pattern to the substrate.

15. An article manufacturing method comprising:
transferring a pattern to a substrate using the lithography apparatus according to claim 1; and
processing a substrate on which the pattern is transferred, wherein
an article is manufactured from the processed substrate.

16. An information processing apparatus that creates a transfer process schedule in a job for a lithography apparatus configured to execute the job of performing pattern transfer on one or more substrates having a plurality of shot regions using one or more originals, the information processing apparatus comprising:
a processor that determines a transfer procedure that can complete the job at maximum speed based on a number of originals to be used in the job and a number of substrates to be processed.

17. A non-transitory computer-readable storage medium storing a program for causing a processor in an information processing apparatus that creates a transfer process schedule in a job for a lithography apparatus configured to execute the job of performing pattern transfer on one or more substrates having a plurality of shot regions using one or more originals to execute
processing of determining a transfer procedure that can complete the job at maximum speed based on a number of originals to be used in the job and a number of substrates to be processed.
